(19) United States
(12) Patent Application Publication
(10) Pub. No.: US 2012/0251955 A1
(43) Pub. Date: Oct. 4, 2012

(54) COMPOSITION FOR FORMATION OF RESIST UNDERLAYER FILM

(75) Inventors: Rikimaru Sakamoto, Toyama-shi (JP); Takafumi Endo, Toyama-shi (JP); BangChing Ho, Toyama-shi (JP)

(73) Assignee: NISSAN CHEMICAL INDUSTRIES, LTD., Tokyo (JP)

(21) Appl. No.: 13/515,960

(22) PCT Filed: Dec. 10, 2010
(86) PCT No.: PCT/JP2010/072237

§ 371 Date: Jun. 14, 2012

(30) Foreign Application Priority Data
Dec. 14, 2009 (JP) 2009-282938

(51) Int. Cl. C09D 163/00; C08K 5/07; G03F 7/20; C08K 5/06

(52) U.S. Cl. 430/296; 523/454; 430/325

(57) ABSTRACT

There is provided a composition for forming a resist underlayer film for electron beam or EUV lithography that is used in a device manufacture process using EUV lithography, reduces the adverse effects caused by an electron beam or EUV, and is effective for the formation of a good resist pattern and a resist pattern formation method using the composition for forming a resist underlayer film for lithography. A composition for forming a resist underlayer film for electron beam or EUV lithography, comprising: a polymer having a repeating unit structure of Formula (1):

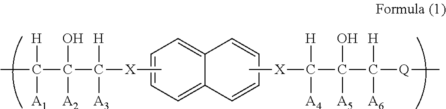

[where Q is a group of Formula (2) or Formula (3):

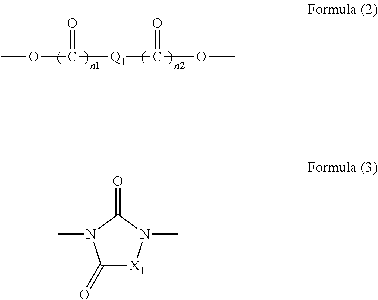

{where Q₁ is a C₁₋₁₀ alkylene group, a phenylene group, a naphthylene group, or an anthrylene group, X₁ is a group of Formula (4), Formula (5), or Formula (6):

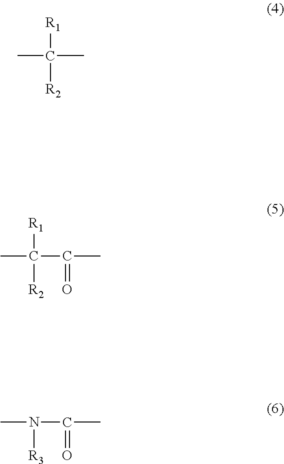

and a solvent.

### TECHNICAL FIELD

The present invention relates to a composition for forming a resist underlayer film for electron beam or EUV lithography that is used in a device manufacture process using EUV lithography, reduces the adverse effects caused by an electron beam or EUV, and is effective for the formation of a good resist pattern and a resist pattern formation method using the composition for forming a resist underlayer film for lithography.

### BACKGROUND ART

Conventionally, microfabrication has been carried out using photolithography techniques in the production of semiconductor devices. The microfabrication is a machining process in which a thin film of a photoresist composition is formed on a substrate to be fabricated such as a silicon wafer, active light such as ultraviolet light is applied onto the film through a mask pattern with a pattern of a semiconductor device followed by development, and the substrate to be fabricated such as a silicon wafer is etched using the obtained photoresist pattern as a protective film. In recent years, semiconductor devices have been further integrated, and the active light to be used has had a shorter wavelength from a KrF excimer laser (248 nm) to an ArF excimer laser (193 nm). Such a change raises serious problems due to the effects of irregular reflections of active light from a substrate and standing waves. To address this, an anti-reflective coating (bottom anti-reflective coating, BARC) has been widely employed between the photoresist and the substrate to be fabricated as a resist underlayer film in order to suppress the effects of reflections.

Known examples of the bottom anti-reflective coating include an inorganic bottom anti-reflective coating composed of, for example, titanium, titanium dioxide, titanium nitride, chromium oxide, carbon, and a-silicon and an organic bottom anti-reflective coating composed of a light absorbing substance and a polymer compound. For the film formation, the former requires an apparatus such as a vacuum deposition system, a CVD system, and a sputtering system, while the latter requires no special apparatus. Due to such an advantage, there have been a large number of studies on the organic bottom anti-reflective coating.

Examples of the organic bottom anti-reflective coating include an acrylic resin-type bottom anti-reflective coating having a hydroxy group as a crosslinkable group and a light-absorbing group in the same molecule (see Patent Document 1) and a novolak resin-type bottom anti-reflective coating having a hydroxy group as a crosslinkable group and a light-absorbing group in the same molecule (see Patent Document 2).

Examples of physical properties desired as the organic bottom anti-reflective coating material include having a large absorbance with respect to light and radiation rays, not causing intermixing with a photoresist layer (being insoluble in a resist solvent), not dispersing low molecular substances from the bottom anti-reflective coating material into an overcoated resist during application or during heating and drying, and having a larger dry etching rate as compared with that of a photoresist (see Non-Patent Documents 1 to 3).

In recent years, as a next-generation photolithography technique subsequent to the photolithography technique using the ArF excimer laser (193 nm), an ArF immersion lithography technique by which exposure is performed through water has been actively studied. However, the photolithography technique using light has been reaching the limit and lithography techniques using an electron beam or EUV having a wavelength of 13.5 nm have been drawing attention as a new lithography technique subsequent to the ArF immersion lithography technique.

In a device manufacture process using the electron beam or EUV lithography, the adverse effects caused by an underlying substrate, an electron beam, or EUV raise problems. For example, a resist pattern for the electron beam or EUV lithography is made into a tailed shape or an undercut shape (hereinafter, also called a bitten shape) and a good straight resist pattern cannot be formed, an unfavorable pattern shape increases pattern sidewall roughness (LER: line edge roughness), and the adhesion between a resist pattern and a substrate is insufficient, thereby causing pattern falling. Thus, the electron beam or EUV lithography process requires, in place of a conventional resist underlayer film (bottom anti-reflective coating) having antireflection properties, a resist underlayer film for electron beam or EUV lithography capable of reducing these adverse effects, forming a good straight resist pattern, and suppressing resist pattern falling.

On the resist underlayer film for electron beam or EUV lithography, a resist is applied after the film formation. Hence, as with the bottom anti-reflective coating, the resist underlayer film for electron beam or EUV lithography essentially requires the characteristics of not causing intermixing with the resist layer (in other words, being insoluble in a resist solvent) and not dispersing low molecular substances from the resist underlayer film to the overcoated resist during application or during heating and drying.

In the stage using the electron beam or EUV lithography, a resist pattern has an extremely small width, and hence a resist for electron beam or EUV lithography is required to be a thinner film. To address this, the time for a removal process of a resist underlayer film by etching is required to be significantly reduced, and this requires a resist underlayer film for electron beam or EUV lithography that can be used as a thin film or a resist underlayer film for electron beam or EUV lithography that has a large selection ratio of the etching rate to that of the resist for electron beam or EUV lithography.

### RELATED ART DOCUMENTS

### Patent Documents

Patent Document 1: U.S. Pat. No. 5,919,599 specification

Patent Document 2: U.S. Pat. No. 5,693,691 specification

### Non-Patent Documents

Non-Patent Document 1: Proc. SPIE, Vol. 3678, 174-185 (1999)

Non-Patent Document 2: Proc. SPIE, Vol. 3678, 800-809 (1999)

Non-Patent Document 3: Proc. SPIE, Vol. 2195, 225-229 (1994)

### SUMMARY OF THE INVENTION

### Problem to be Solved by the Invention

An object of the present invention is to provide a composition for forming a resist underlayer film for electron beam or EUV lithography in order to be used in an electron beam or EUV lithography process in production of semiconductor devices. Another object of the present invention is to provide the composition for forming a resist underlayer film that reduces adverse effects caused by an underlying substrate, an electron beam, or EUV to form a form a good straight resist pattern and can consequently improve a resist sensitivity, that does not cause intermixing with a resist layer, and that forms a resist underlayer film for EUV lithography having a larger dry etching rate as compared with that of a resist. Further another object of the present invention is to provide a method for forming a resist pattern using the composition for forming a resist underlayer film.

### Means for Solving the Problem

The present invention relates to, as a first aspect, a composition for forming a resist underlayer film for electron beam or EUV lithography, the composition including: a polymer having a repeating unit structure of Formula (1):

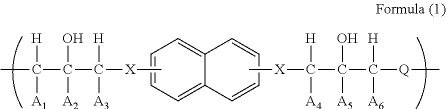

[where X is an ester linkage or an ether linkage; each of A₁, A₂, A₃, A₄, A₅, and A₆ is a hydrogen atom, a methyl group, or an ethyl group, and Q is a group of Formula (2) or Formula (3):

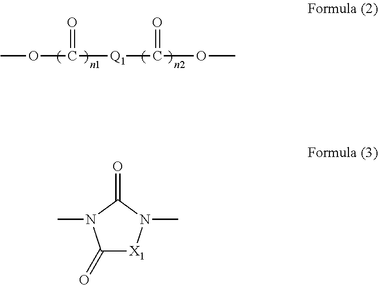

{where Q₁ is a C₁₋₁₀ alkylene group, a phenylene group, a naphthylene group, or an anthrylene group, and each of the phenylene group, the naphthylene group, and the anthrylene group is optionally substituted with a group selected from a group consisting of a C₁₋₆ alkyl group, a halogen atom, a C₁₋₆ alkoxy group, a nitro group, a cyano group, a hydroxy group, and a C₁₋₆ alkylthio group; each of n₁ and n₂ is a number of 0 or 1; and X₁ is a group of Formula (4), Formula (5), or Formula (6):

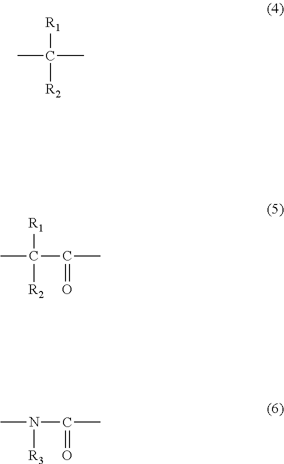

(where each of R₁ and R₂ is a hydrogen atom, a C₁₋₆ alkyl group, a C₂₋₆ alkenyl group, a benzyl group, or a phenyl group, the benzyl group and the phenyl group are optionally substituted with a group selected from a group consisting of a C₁₋₆ alkyl group, a halogen atom, a C₁₋₆ alkoxy group, a nitro group, a cyano group, a hydroxy group, and a C₁₋₆ alkylthio group, and R₁ and R₂ are optionally bonded to each other to form a C₃₋₆ ring; and R₃ is a C₁₋₆ alkyl group, a C₂₋₆ alkenyl group, a benzyl group, or a phenyl group, and the benzyl group and the phenyl group are optionally substituted with a group selected from a group consisting of a C₁₋₆ alkyl group, a halogen atom, a C₁₋₆ alkoxy group, a nitro group, a cyano group, a hydroxy group, and a C₁₋₆ alkylthio group)}]; and a solvent,

as a second aspect, a composition for forming a resist underlayer film for electron beam or EUV lithography, the composition including a polymer produced by polyaddition reaction of a compound of Formula (7):

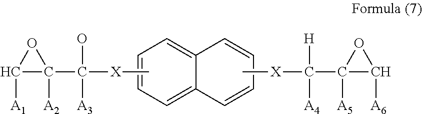

with a compound of Formula (8) or Formula (9):

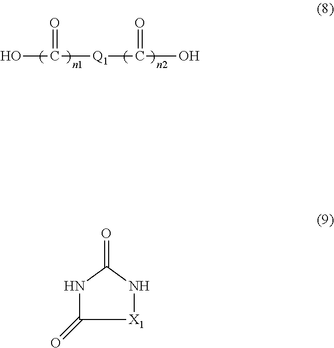

and a solvent
[where X is an ester linkage or an ether linkage; each of A₁, A₂, A₃, A₄, A₅, and A₆ is a hydrogen atom, a methyl group, or an ethyl group; Q₁ is a C₁₋₁₀ alkylene group, a phenylene group, a naphthylene group, or an anthrylene group, and each of the phenylene group, the naphthylene group, and the anthrylene group is optionally substituted with a group selected from a group consisting of a C₁₋₆ alkyl group, a halogen atom, a C₁₋₆ alkoxy group, a nitro group, a cyano group, a hydroxy group, and a C₁₋₆ alkylthio group; each of n₁ and n₂ is a number of 0 or 1; and X₁ is a group of Formula (4), Formula (5), or Formula (6):

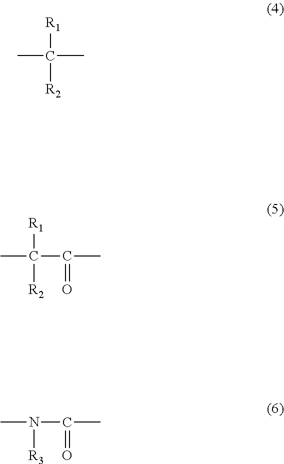

(where each of R₁ and R₂ is a hydrogen atom, a C₁₋₆ alkyl group, a C₂₋₆ alkenyl group, a benzyl group, or a phenyl group, the benzyl group and the phenyl group are optionally substituted with a group selected from a group consisting of a C₁₋₆ alkyl group, a halogen atom, a C₁₋₆ alkoxy group, a nitro group, a cyano group, a hydroxy group, and a C₁₋₆ alkylthio group, and R₁ and R₂ are optionally bonded to each other to form a C₃₋₆ ring; and R₃ is a C₁₋₆ alkyl group, a C₂₋₆ alkenyl group, a benzyl group, or a phenyl group, and the benzyl group and the phenyl group are optionally substituted with a group selected from a group consisting of a C₁₋₆ alkyl group, a halogen atom, a C₁₋₆ alkoxy group, a nitro group, a cyano group, a hydroxy group, and a C₁₋₆ alkylthio group)],

as a third aspect, the composition for faulting a resist underlayer film for electron beam or EUV lithography according to the second aspect, in which the compound of Formula (7) is a compound of Formula (10) or Formula (11):

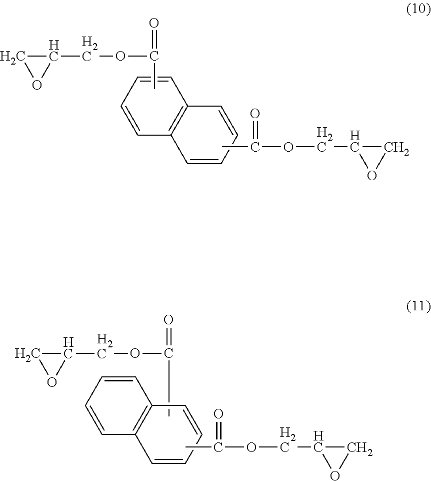

as a fourth aspect, a composition for forming a resist underlayer film for electron beam or EUV lithography, the composition including a polymer produced by polyaddition reaction of a compound of Formula (12):

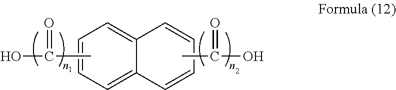

with a compound of Formula (13) or Formula (14):

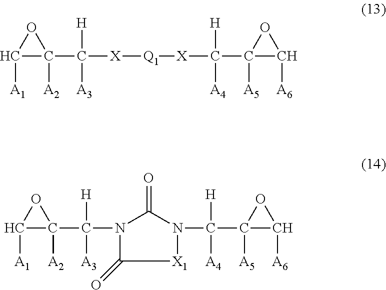

and a solvent
[where X is an ester linkage or an ether linkage; each of A₁, A₂, A₃, A₄, A₅, and A₆ is a hydrogen atom, a methyl group, or an ethyl group; Q₁ is a C₁₋₁₀ alkylene group, a phenylene group, a naphthylene group, or an anthrylene group, and each of the phenylene group, the naphthylene group, and the anthrylene group is optionally substituted with a group selected from a group consisting of a C₁₋₆ alkyl group, a halogen atom, a C₁₋₆ alkoxy group, a nitro group, a cyano group, a hydroxy group, and a C₁₋₆ alkylthio group; each of n₁ and n₂ is a number of 0 or 1; and X₁ is a group of Formula (4), Formula (5), or Formula (6):

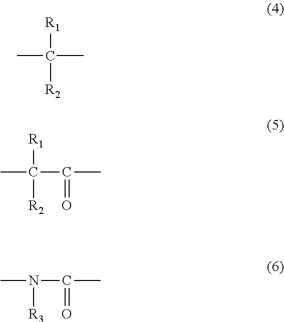

(where each of R₁ and R₂ is a hydrogen atom, a C₁₋₆ alkyl group, a C₂₋₆ alkenyl group, a benzyl group, or a phenyl group, the benzyl group and the phenyl group are optionally substituted with a group selected from a group consisting of a C₁₋₆ alkyl group, a halogen atom, a C₁₋₆ alkoxy group, a nitro group, a cyano group, a hydroxy group, and a C₁₋₆ alkylthio group, and R₁ and R₂ are optionally bonded to each other to form a C₃₋₆ ring; and R₃ is a C₁₋₆ alkyl group, a C₂₋₆ alkenyl group, a benzyl group, or a phenyl group, and the benzyl group and the phenyl group are optionally substituted with a group selected from a group consisting of a C₁₋₆ alkyl group, a halogen atom, a C₁₋₆ alkoxy group, a nitro group, a cyano group, a hydroxy group, and a C₁₋₆ alkylthio group)],

as a fifth aspect, the composition for forming a resist underlayer film for electron beam or EUV lithography according to the fourth aspect, in which the compound of Formula (12) is a compound of Formula (15) or Formula (16):

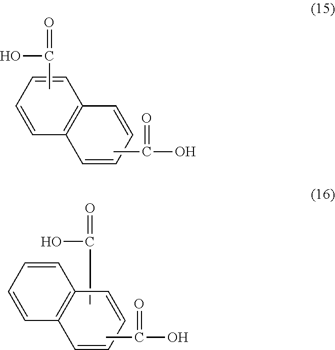

as a sixth aspect, the composition for forming a resist underlayer film for electron beam or EUV lithography according to any one of the first aspect to the fifth aspect, the composition further including a crosslinkable compound,

as a seventh aspect, the composition for forming a resist underlayer film for electron beam or EUV lithography according to the sixth aspect, in which the crosslinkable compound is a nitrogen-containing compound having two to four nitrogen atoms substituted with a methylol group or an alkoxymethyl group,

as an eighth aspect, the composition for forming a resist underlayer film for electron beam or EUV lithography according to any one of the first aspect to the seventh aspect, the composition further including an acid compound,

as a ninth aspect, the composition for forming a resist underlayer film for electron beam or EUV lithography according to the eighth aspect, in which the acid compound is a sulfonic acid compound,

as a tenth aspect, the composition for forming a resist underlayer film for electron beam or EUV lithography according to the ninth aspect, in which the acid compound is a combination of an iodonium salt-type acid generator or a sulfonium salt-type acid generator with the sulfonic acid compound,

as an eleventh aspect, a method for forming a photoresist pattern used for producing a semiconductor device, the method including applying the composition for forming a resist underlayer film according to any one of the first aspect to the tenth aspect on a semiconductor substrate followed by baking the obtained substance to form a resist underlayer film, forming a photoresist layer on the resist underlayer film, exposing the semiconductor substrate coated with the resist underlayer film and the photoresist layer, and developing the photoresist layer after the exposure, and

as a twelfth aspect, the method for forming a photoresist pattern according to the eleventh aspect, in which the exposing is carried out by an electron beam or EUV having a wavelength of 13.5 nm.

### Effect of the Invention

A resist underlayer film obtained from the composition for forming a resist underlayer film for electron beam or EUV lithography of the present invention reduces the adverse effects caused by an underlying substrate, an electron beam, or EUV in a resist process to form a good straight resist pattern and can consequently improve a resist sensitivity. The resist underlayer film also has a larger dry etching rate as compared with that of a resist film formed as an upper layer of the resist underlayer film and can consequently easily transfer a resist pattern onto a substrate to be processed or a film to be processed on a substrate through a dry etching process.

In addition, the underlayer film formed from the composition for forming a resist underlayer film for lithography of the present invention has excellent adhesion to a resist film, a substrate, or a film to be processed on a substrate.

Unlike a resist underlayer film (bottom anti-reflective coating) used in a photolithography process, a resist underlayer film formed from the composition for forming a resist underlayer film for electron beam or EUV lithography of the present invention is formed beneath a resist film for electron beam or EUV lithography to control a resist pattern shape at the time of electron beam or EUV lithography, suppresses the tailing or biting of a pattern bottom part, and can achieve a rectangle shape in a pattern cross section. Therefore, such a resist underlayer film can suppress the increase in side wall roughness (LER: line edge roughness) in a resist pattern. The resist underlayer film also obtains high adhesion to a substrate or a film to be processed on a substrate and a resist formed with a pattern and can suppress pattern falling.

### MODES FOR CARRYING OUT THE INVENTION

The present invention relates to a composition for forming a resist underlayer film for electron beam or EUV lithography, which is used for the manufacture of semiconductor devices employing an electron beam or EUV lithography technique. While a resist underlayer film (bottom anti-reflective coating) used in a conventional photolithography process is required to have a performance of suppressing reflected light generated from a substrate, a resist underlayer film that is formed from the composition for forming a resist underlayer film for such an application is not required to have such a performance. From such a viewpoint, the composition of the present invention is completed by including the following composition.

The composition for forming a resist underlayer film includes a polymer having a repeating unit of Formula (1) and a solvent and may further include a cross-linking agent, a cross-linking catalyst, and a surfactant.

The composition for forming a resist underlayer film for electron beam or EUV lithography of the present invention has a solid content of 0.1 to 50% by mass and preferably 0.5 to 30% by mass. The solid content is a content of the composition for forming a resist underlayer film except for the solvent component.

The composition for forming a resist underlayer film includes the polymer having the repeating unit of Formula (1) in an amount of 20% by mass or more, for example, 20 to 100% by mass, 30 to 100% by mass, 50 to 90% by mass, or 60 to 80% by mass, in the solid content.

The polymer having the repeating unit of Formula (1) may have a weight average molecular weight of, for example, 1,000 to 100,000, 1,000 to 50,000, or 1,000 to 20,000.

In the repeating unit of Formula (1), X is an ester linkage or an ether linkage. In the ester linkage, the carbon atom in the carbonyl group is preferably bonded to the aromatic ring moiety. Each of A₁, A₂, A₃, A₄, A₅, and A₆ is a hydrogen atom, a methyl group, or an ethyl group. The group Q is represented by Formula (2) or Formula (3). Q₁ representing a group in the group Q is a C₁₋₁₀ alkylene group, a phenylene group, a naphthylene group, or an anthrylene group, and each of the phenylene group, the naphthylene group, and the anthrylene group may be substituted with a group selected from a group consisting of a C₁₋₆ alkyl group, a halogen atom, a C₁₋₆ alkoxy group, a nitro group, a cyano group, a hydroxy group, and a C₁₋₆ alkylthio group. Each of n₁ and n₂ is a number of 0 or 1. When n₁ and n₂ are 0, the group Q has an ether linkage, while when n₁ and n₂ are 1, the group Q has an ester linkage. X₁ is represented by Formula (4), Formula (5), or Formula (6).

In Formulae, each of R₁ and R₂ is a hydrogen atom, a C₁₋₆ alkyl group, a C₂₋₆ alkenyl group, a benzyl group, or a phenyl group, and the benzyl group and the phenyl group may be substituted with a group selected from a group consisting of a C₁₋₆ alkyl group, a halogen atom, a C₁₋₆ alkoxy group, a nitro group, a cyano group, a hydroxy group, and a C₁₋₆ alkylthio group. R₁ and R₂ may be bonded to each other to form a C₃₋₆ ring. R₃ is a C₁₋₆ alkyl group, a C₂₋₆ alkenyl group, a benzyl group, or a phenyl group, and the benzyl group and the phenyl group may be substituted with a group selected from a group consisting of a C₁₋₆ alkyl group, a halogen atom, a C₁₋₆ alkoxy group, a nitro group, a cyano group, a hydroxy group, and a C₁₋₆ alkylthio group.

The polymer having the repeating unit of Formula (1) can be produced by polyaddition reaction of a compound of Formula (7) with a compound of Formula (8) or Formula (9).

X is an ester linkage or an ether linkage. In the ester linkage, the carbon atom in the carbonyl group is preferably bonded to the aromatic ring moiety. Each of A₁, A₂, A₃, A₄, A₅, and A₆ is a hydrogen atom, a methyl group, or an ethyl group. Q₁ is a C₁₋₁₀ alkylene group, a phenylene group, a naphthylene group, or an anthrylene group, and each of the phenylene group, the naphthylene group, and the anthrylene group may be substituted with a group selected from a group consisting of a C₁₋₆ alkyl group, a halogen atom, a C₁₋₆ alkoxy group, a nitro group, a cyano group, a hydroxy group, and a C₁₋₆ alkylthio group. Each of n₁ and n₂ is a number of 0 or 1. When n₁ and n₂ are 0, a produced polymer has an ether linkage, while when n₁ and n₂ are 1, a produced polymer has an ester linkage.

X₁ is represented by Formula (4), Formula (5), or Formula (6), which may be as described above.

As the compound of Formula (7), for example, a compound of Formula (10) or Formula (11) may be used. Examples of the compound of Formula (8) include isophthalic acid and hydroxyisophthalic acid. Examples of the compound of Formula (9) include barbituric acid, cyanuric acid, and isocyanuric acid.

The polymer having the repeating unit of Formula (1) can be produced by polyaddition reaction of a compound of Formula (12) with a compound of Formula (13) or Formula (14).

X is an ester linkage or an ether linkage. In the ester linkage, the carbon atom in the carbonyl group is preferably bonded to the aromatic ring moiety. Each of A₁, A₂, A₃, A₄, A₅, and A₆ is a hydrogen atom, a methyl group, or an ethyl group. Q₁ is a C₁₋₁₀ alkylene group, a phenylene group, a naphthylene group, or an anthrylene group, and each of the phenylene group, the naphthylene group, and the anthrylene group may be substituted with a group selected from a group consisting of a C₁₋₆ alkyl group, a halogen atom, a C₁₋₆ alkoxy group, a nitro group, a cyano group, a hydroxy group, and a C₁₋₆ alkylthio group. Each of n₁ and n₂ is a number of 0 or 1. When n₁ and n₂ are 0, a produced polymer has an ether linkage, while when n₁ and n₂ are 1, a produced polymer has an ester linkage.

X₁ is represented by Formula (4), Formula (5), or Formula (6), which may be as described above.

As the compound of Formula (12), for example, a compound of Formula (15) or Formula (16) may be used.

Examples of the alkylene group include a methylene group, an ethylene group, an n-propylene group, an isopropylene group, a cyclopropylene group, an n-butylene group, an isobutylene group, an s-butylene group, a t-butylene group, a cyclobutylene group, a 1-methyl-cyclopropylene group, a 2-methyl-cyclopropylene group, an n-pentylene group, a 1-methyl-n-butylene group, a 2-methyl-n-butylene group, a 3-methyl-n-butylene group, a 1,1-dimethyl-n-propylene group, a 1,2-dimethyl-n-propylene group, a 2,2-dimethyl-n-propylene group, a 1-ethyl-n-propylene group, a cyclopentylene group, a 1-methyl-cyclobutylene group, a 2-methyl-cyclobutylene group, a 3-methyl-cyclobutylene group, a 1,2-dimethyl-cyclopropylene group, a 2,3-dimethyl-cyclopropylene group, a 1-ethyl-cyclopropylene group, a 2-ethyl-cyclopropylene group, an n-hexylene group, a 1-methyl-n-pentylene group, a 2-methyl-n-pentylene group, a 3-methyl-n-pentylene group, a 4-methyl-n-pentylene group, a 1,1-dimethyl-n-butylene group, a 1,2-dimethyl-n-butylene group, a 1,3-dimethyl-n-butylene group, a 2,2-dimethyl-n-butylene group, a 2,3-dimethyl-n-butylene group, a 3,3-dimethyl-n-butylene group, a 1-ethyl-n-butylene group, a 2-ethyl-n-butylene group, a 1,1,2-trimethyl-n-propylene group, a 1,2,2-trimethyl-n-propylene group, a 1-ethyl-l-methyl-n-propylene group, a 1-ethyl-2-methyl-n-propylene, a cyclohexylene group, a 1-methyl-cyclopentylene group, a 2-methyl-cyclopentylene group, a 3-methyl-cyclopentylene group, a 1-ethyl-cyclobutylene group, a 2-ethyl-cyclobutylene group, a 3-ethyl-cyclobutylene group, a 1,2-dimethyl-cyclobutylene group, a 1,3-dimethyl-cyclobutylene group, a 2,2-dimethyl-cyclobutylene group, a 2,3-dimethyl-cyclobutylene group, a 2,4-dimethyl-cyclobutylene group, a 3,3-dimethyl-cyclobutylene group, a 1-n-propyl-cyclopropylene group, a 2-n-propyl-cyclopropylene group, a 1-isopropyl-cyclopropylene group, a 2-isopropyl-cyclopropylene group, a 1,2,2-trimethyl-cyclopropylene group, a 1,2,3-trimethyl-cyclopropylene group, a 2,2,3-trimethyl-cyclopropylene group, a 1-ethyl-2-methyl-cyclopropylene group, a 2-ethyl-1-methyl-cyclopropylene group, a 2-ethyl-2-methyl-cyclopropylene group, and a 2-ethyl-3-methyl-cyclopropylene group.

Examples of the halogen group include a fluoro group, a chloro group, a bromo group, and an iodo group.

Examples of the alkoxy group include a methoxy group, an ethoxy group, an n-propoxy group, an i-propoxy group, an n-butoxy group, an i-butoxy group, an s-butoxy group, a t-butoxy group, an n-pentoxy group, a 1-methyl-n-butoxy group, a 2-methyl-n-butoxy group, a 3-methyl-n-butoxy group, a 1,1-dimethyl-n-propoxy group, a 1,2-dimethyl-n-propoxy group, a 2,2-dimethyl-n-propoxy group, a 1-ethyl-n-propoxy group, an n-hexyloxy group, a 1-methyl-n-pentyloxy group, a 2-methyl-n-pentyloxy group, a 3-methyl-n-pentyloxy group, a 4-methyl-n-pentyloxy group, a 1,1-dimethyl-n-butoxy group, a 1,2-dimethyl-n-butoxy group, a 1,3-dimethyl-n-butoxy group, a 2,2-dimethyl-n-butoxy group, a 2,3-dimethyl-n-butoxy group, a 3,3-dimethyl-n-butoxy group, a 1-ethyl-n-butoxy group, a 2-ethyl-n-butoxy group, a 1,1,2-trimethyl-n-propoxy group, a 1,2,2,-trimethyl-n-propoxy group, a 1-ethyl-1-methyl-n-propoxy group, and a 1-ethyl-2-methyl-n-propoxy group.

Examples of the alkylthio group include an ethylthio group, a butylthio group, a hexylthio group, and an octylthio group.

Examples of the alkenyl group include an ethenyl group, a 1-propenyl group, a 2-propenyl group, a 1-methyl-1-ethenyl group, a 1-butenyl group, a 2-butenyl group, a 3-butenyl group, a 2-methyl-1-propenyl group, a 2-methyl-2-propenyl group, a 1-ethylethenyl group, a 1-methyl-1-propenyl group, a 1-methyl-2-propenyl group, a 1-pentenyl group, a 2-pentenyl group, a 3-pentenyl group, a 4-pentenyl group, a 1-n-propylethenyl group, a 1-methyl-1-butenyl group, a 1-methyl-2-butenyl group, a 1-methyl-3-butenyl group, a 2-ethyl-2-propenyl group, a 2-methyl-1-butenyl group, a 2-methyl-2-butenyl group, a 2-methyl-3-butenyl group, a 3-methyl-1-butenyl group, a 3-methyl-2-butenyl group, a 3-methyl-3-butenyl group, a 1,1-dimethyl-2-propenyl group, a 1-i-propylethenyl group, a 1,2-dimethyl-1-propenyl group, a 1,2-dimethyl-2-propenyl group, a 1-cyclopentenyl group, a 2-cyclopentenyl group, a 3-cyclopentenyl group, a 1-hexenyl group, a 2-hexenyl group, a 3-hexenyl group, a 4-hexenyl group, a 5-hexenyl group, a 1-methyl-1-pentenyl group, a 1-methyl-2-pentenyl group, a 1-methyl-3-pentenyl group, a 1-methyl-4-pentenyl group, a 1-n-butylethenyl group, a 2-methyl-1-pentenyl group, a 2-methyl-2-pentenyl group, a 2-methyl-3-pentenyl group, a 2-methyl-4-pentenyl group, a 2-n-propyl-2-propenyl group, a 3-methyl-1-pentenyl group, a 3-methyl-2-pentenyl group, a 3-methyl-3-pentenyl group, a 3-methyl-4-pentenyl group, a 3-ethyl-3-butenyl group, a 4-methyl-1-pentenyl group, a 4-methyl-2-pentenyl group, a 4-methyl-3-pentenyl group, a 4-methyl-4-pentenyl group, a 1,1-dimethyl-2-butenyl group, a 1,1-dimethyl-3-butenyl group, a 1,2-dimethyl-1-butenyl group, a 1,2-dimethyl-2-butenyl group, a 1,2-dimethyl-3-butenyl group, a 1-methyl-2-ethyl-2-propenyl group, a 1-s-butylethenyl group, a 1,3-dimethyl-1-butenyl group, a 1,3-dimethyl-2-butenyl group, a 1,3-dimethyl-3-butenyl group, a 1-i-butylethenyl group, a 2,2-dimethyl-3-butenyl group, a 2,3-dimethyl-1-butenyl group, a 2,3-dimethyl-2-butenyl group, a 2,3-dimethyl-3-butenyl group, a 2-i-propyl-2-propenyl group, a 3,3-dimethyl-1-butenyl group, a 1-ethyl-1-butenyl group, a 1-ethyl-2-butenyl group, a 1-ethyl-3-butenyl group, a 1-n-propyl-1-propenyl group, a 1-n-propyl-2-propenyl group, a 2-ethyl-1-butenyl group, a 2-ethyl-2-butenyl group, a 2-ethyl-3-butenyl group, a 1,1,2-trimethyl-2-propenyl group, a 1-t-butylethenyl group, a 1-methyl-1-ethyl-2-propenyl group, a 1-ethyl-2-methyl-1-propenyl group, a 1-ethyl-2-methyl-2-propenyl group, a 1-i-propyl-1-propenyl group, a 1-i-propyl-2-propenyl group, a 1-methyl-2-cyclopentenyl group, a 1-methyl-3-cyclopentenyl group, a 2-methyl-1-cyclopentenyl group, a 2-methyl-2-cyclopentenyl group, a 2-methyl-3-cyclopentenyl group, a 2-methyl-4-cyclopentenyl group, a 2-methyl-5-cyclopentenyl group, a 2-methylene-cyclopentyl group, a 3-methyl-1-cyclopentenyl group, a 3-methyl-2-cyclopentenyl group, a 3-methyl-3-cyclopentenyl group, a 3-methyl-4-cyclopentenyl group, a 3-methyl-5-cyclopentenyl group, a 3-methylene-cyclopentyl group, a 1-cyclohexenyl group, a 2-cyclohexenyl group, and a 3-cyclohexenyl group.

A resist underlayer film formed from the composition for forming a resist underlayer film of the present invention is preferably cross-linked by heating after the application in order to suppress the intermixing with an overcoating photoresist, and the composition for forming a resist underlayer film of the present invention may further include a cross-linking agent component. Examples of the cross-linking agent include a melamine compound and a substituted urea compound having a crosslinkable substituent such as a methylol group and a methoxymethyl group and a polymer compound containing an epoxy group. Preferred examples of such an agent include a cross-linking agent having at least two crosslinkable substituents such as a methoxymethylated glycoluril and a methoxymethylated melamine, and tetramethoxymethylglycoluril or hexamethoxymethylolmelamine is particularly preferred. The amount of the cross-linking agent added varies depending on, for example, a coating solvent to be used, an underlying substrate to be used, a solution viscosity to be required, and a film shape to be required, but is 0.001 to 20 parts by mass, preferably 0.01 to 15 parts by mass, and more preferably 0.05 to 10 parts by mass, based on 100 parts by mass of the total composition. Such a cross-linking agent may cause cross-linking reaction by self-condensation, but when a polymer used in the composition for forming a resist underlayer film of the present invention has a crosslinkable substituent, the cross-linking agent can cause the cross-linking reaction with the crosslinkable substituent.

As a catalyst for accelerating the cross-linking reaction, the composition may include an acidic compound such as p-toluenesulfonic acid, trifluoromethanesulfonic acid, salicylic acid, sulfosalicylic acid, citric acid, benzoic acid, and hydroxybenzoic acid and/or a thermal acid generator such as 2,4,4,6-tetrabromocyclohexadienone, benzoin tosylate, 2-nitrobenzyl tosylate, and pyridinium p-toluenesulfonate. Such a catalyst is included in an amount of 0.01 to 10 parts by mass and preferably 0.01 to 5 parts by mass based on 100 parts by mass of the total solid content.

The composition for forming a resist underlayer film for electron beam or EUV lithography of the present invention may include an acid generator that generates an acid by irradiation of an electron beam or EUV in order to match the acidity to that of a resist applied as an upper layer of the resist underlayer film formed from the composition in a lithography process. Preferred examples of the acid generator include onium salt compound-type acid generators such as bis(4-tert-butylphenyl)iodonium trifluoromethanesulfonate and triphenylsulfonium trifluoromethanesulfonate; halogen-containing compound-type acid generators such as phenyl-bis(trichloromethyl)-s-triazine; and sulfonic acid compound-type acid generators such as benzoin tosylate and N-hydroxysuccinimide trifluoromethanesulfonate. The acid generator is included in an amount of 0.02 to 3 parts by mass and preferably 0.04 to 2 parts by mass based on 100 parts by mass of the total solid content.

The composition for forming a resist underlayer film for electron beam or EUV lithography of the present invention may further include a rheology control agent, an adhesion assistant, a surfactant, and the like as necessary in addition to the above components.

The rheology control agent is added primarily in order to improve flowability of the composition for forming a resist underlayer film. Specific examples of the rheology control agent include a phthalic acid derivative such as dimethyl phthalate, diethyl phthalate, diisobutyl phthalate, dihexyl phthalate, and butyl isodecyl phthalate; an adipic acid derivative such as di-n-butyl adipate, diisobutyl adipate, diisooctyl adipate, and octyl decyl adipate; a maleic acid derivative such as di-n-butyl maleate, diethyl maleate, and dinonyl maleate; an oleic acid derivative such as methyl oleate, butyl oleate, and tetrahydrofurfuryl oleate; and a stearic acid derivative such as n-butyl stearate and glyceryl stearate. Such a rheology control agent is commonly included in a ratio of less than 30 parts by mass based on 100 parts by mass of the total composition of the composition for forming a resist underlayer film.

The adhesion assistant is added primarily in order to improve adhesion between a substrate, a film to be processed on a substrate, or a resist and the composition for forming a resist underlayer film, and especially in order not to remove a resist during development. Specific examples of the adhesion assistant include chlorosilanes such as trimethylchlorosilane, dimethylvinylchlorosilane, methyldiphenylchlorosilane, and chloromethyldimethylchlorosilane; alkoxysilanes such as trimethylmethoxysilane, dimethyldiethoxysilane, methyldimethoxysilane, dimethylvinylethoxysilane, diphenyldimethoxysilane, and phenyltriethoxysilane; silazanes such as hexamethyldisilazane, N,N′-bis(trimethylsilyl)urea, dimethyltrimethylsilylamine, and trimethylsilylimidazole; silanes such as vinyltrichlorosilane, γ-chloropropyltrimethoxysilane, γ-aminopropyltriethoxysilane, and γ-glycidoxypropyltrimethoxysilane; heterocyclic compounds such as benzotriazole, benzimidazole, indazole, imidazole, 2-mercaptobenzimidazole, 2-mercaptobenzothiazole, 2-mercaptobenzoxazole, urazole, thiouracil, mercaptoimidazole, and mercaptopyrimidine; ureas such as 1,1-dimethylurea and 1,3-dimethylurea; and thiourea compounds. Such an adhesion assistant is commonly included in a ratio of less than 5 parts by mass and preferably less than 2 parts by mass based on 100 parts by mass of the total composition of the composition for forming a resist underlayer film.

The composition for forming a resist underlayer film of the present invention may include a surfactant in order not to generate pinholes, stration, or the like on a resist underlayer film formed form the composition and in order to further improve the coating properties against surface irregularity on a substrate and the like. Examples of the surfactant include nonionic surfactants including polyoxyethylene alkyl ethers such as polyoxyethylene lauryl ether, polyoxyethylene stearyl ether, polyoxyethylene cetyl ether, and polyoxyethylene oleyl ether; polyoxyethylene alkylallyl ethers such as polyoxyethylene octylphenol ether and polyoxyethylene nonylphenol ether; polyoxyethylene-polyoxypropylene block copolymers; sorbitan fatty acid esters such as sorbitan monolaurate, sorbitan monopalmitate, sorbitan monostearate, sorbitan monooleate, sorbitan trioleate, and sorbitan tristearate; and polyoxyethylene sorbitan fatty acid esters such as polyoxyethylene sorbitan monolaurate, polyoxyethylene sorbitan monopalmitate, polyoxyethylene sorbitan monostearate, polyoxyethylene sorbitan trioleate, and polyoxyethylene sorbitan tristearate; fluorochemical surfactants including EFTOP EF301, EF303, and EF352 (manufactured by Tochem Products), MEGAFAC F171 and F173 (manufactured by Dainippon Ink and Chemicals, Inc.), Fluorad FC430 and FC431 (manufactured by Sumitomo 3M), and Asahiguard AG710, Surflon S-382, SC101, SC102, SC103, SC104, SC105, and SC106 (manufactured by Asahi Glass Co., Ltd.); and organosiloxane polymer KP 341 (manufactured by Shin-Etsu Chemical Co., Ltd.). Such a surfactant is commonly included in an amount of 0.2 part by mass or less and preferably 0.1 part by mass or less based on 100 parts by mass of the total composition of the composition for forming a resist underlayer film of the present invention. These surfactants may be added singly or in combination of two or more of them.

Usable examples of the solvent dissolving the polymer include ethylene glycol monomethyl ether, ethylene glycol monoethyl ether, methyl cellosolve acetate, ethyl cellosolve acetate, diethylene glycol monomethyl ether, diethylene glycol monoethyl ether, propylene glycol, propylene glycol monomethyl ether, propylene glycol monomethyl ether acetate, propylene glycol propyl ether acetate, toluene, xylene, methyl ethyl ketone, cyclopentanone, cyclohexanone, ethyl 2-hydroxypropionate, ethyl 2-hydroxy-2-methylpropionate, ethyl ethoxyacetate, ethyl hydroxyacetate, methyl 2-hydroxy-3-methylbutanoate, methyl 3-methoxypropionate, ethyl 3-methoxypropionate, ethyl 3-ethoxypropionate, methyl 3-ethoxypropionate, methyl pyruvate, ethyl pyruvate, ethyl acetate, butyl acetate, ethyl lactate, and butyl lactate. These organic solvents may be used singly or in combination of two or more of them.

High-boiling solvents such as propylene glycol monobutyl ether and propylene glycol monobutyl ether acetate may be mixed to be used. Among these solvents, propylene glycol monomethyl ether, propylene glycol monomethyl ether acetate, ethyl lactate, butyl lactate, and cyclohexanone are preferred in order to improve leveling properties.

An electron beam or EUV resist that is applied as an upper layer of the resist underlayer film for lithography in the present invention may be positive or negative. Examples of the resist include a chemically amplified resist composed of an acid generator and a binder having a group that is degraded by an acid to change an alkali dissolution rate, a chemically amplified resist composed of an alkali soluble binder, an acid generator, and a low molecular compound that is degraded by an acid to change an alkali dissolution rate of a resist, a chemically amplified resist composed of an acid generator, a binder having a group that is degraded by an acid to change an alkali dissolution rate, and a low molecular compound that is degraded by an acid to change an alkali dissolution rate of a resist, a non-chemically amplified resist composed of a binder having a group that is degraded by an electron beam or EUV to change an alkali dissolution rate, and a non-chemically amplified resist composed of a binder having a moiety that is cleaved by an electron beam or EUV to change an alkali dissolution rate.

Usable examples of the developer for a positive-type resist having a resist underlayer film formed from the composition for forming a resist underlayer film of the present invention include aqueous solutions of alkalis including inorganic alkalis such as sodium hydroxide, potassium hydroxide, sodium carbonate, sodium silicate, sodium metasilicate, and aqueous ammonia; primary amines such as ethylamine and n-propylamine; secondary amines such as diethylamine and di-n-butylamine; tertiary amines such as triethylamine and methyldiethylamine; alcohol amines such as dimethylethanolamine and triethanolamine; quaternary ammonium salts such as tetramethylammonium hydroxide, tetraethylammonium hydroxide, and choline; and cyclic amines such as pyrrole and piperidine. Such an aqueous alkali solution may include alcohols such as isopropyl alcohol or a surfactant such as a nonionic surfactant in a suitable amount for use. Among these developers, the quaternary ammonium salts are preferred, and tetramethylammonium hydroxide and choline are more preferred.

In the present invention, application of the composition for forming a resist underlayer film onto a substrate or a substrate having a film to be processed followed by baking the composition enables the formation of a resist underlayer film.

In the present invention, a semiconductor device is produced by applying the composition for forming a resist underlayer film onto a substrate on which a transferring pattern is formed or a film to be processed on a substrate followed by baking the composition to form a resist underlayer film, coating the resist underlayer film with a resist for electron beam or EUV lithography, applying an electron beam or EUV to the substrate coated with the resist underlayer film and the resist through a predetermined mask followed by development, and transferring an image onto the substrate or the film to be processed on a substrate by dry etching to form an integrated circuit device.

A semiconductor device to which the composition for forming a resist underlayer film of the present invention is applied has a structure in which, on a substrate, if desired, a film to be processed for transferring a pattern, a resist underlayer film, and a resist are formed in this order. The resist underlayer film is formed by applying the composition for forming a resist underlayer film containing a polymer compound and a solvent onto the film to be processed to which a pattern is transferred followed by heat treatment. The resist underlayer film reduces the adverse effects caused by an underlying substrate, an electron beam, or EUV to form a good straight resist pattern, and can achieve a margin sufficient to an irradiation amount of electron beam or EUV. The resist underlayer film has a larger dry etching rate as compared with that of a resist film formed as an upper layer of the resist underlayer film and can easily transfer a resist pattern to a substrate or a film to be processed on a substrate through a dry etching process.

### EXAMPLES

### Synthesis Example 1

A mixture of 100.00 g of 2,6-naphthalenedicarboxylic acid, 1,283.85 g of epichlorohydrin, and 2.20 g of tetramethylammonium chloride was stirred at 90° C. for 4 hours for dissolution and was further reacted for 4 hours. Then, the temperature was lowered to 65° C., 55.5 g of ground NaOH powder was gradually added into the system, and the whole was stirred for 15 minutes. A white precipitate was filtered off and 500 g of epichlorohydrin was added. Then, the mixture was shaken with 500 g of pure water for washing, and the separated organic layer was dried over sodium sulfate. After the drying, the solvent was removed under reduced pressure for concentration, and the precipitated solid was filtered off. The obtained solid was washed with chloroform and diethyl ether and dried under reduced pressure to afford diglycidyl 2,6-naphthalenedicarboxylate as a target compound.

### Synthesis Example 2

In 161.24 g of propylene glycol monomethyl ether, 25.00 g of diglycidyl terephthalate (manufactured by Nagase ChemteX Corporation, product name: EX711), 14.33 g of isophthalic acid, and 0.98 g of benzyltriethylammonium chloride were dissolved and the whole was reacted at 130° C. for 4 hours to give a polymer compound solution. Subjecting the obtained polymer compound to GPC analysis, it was revealed that the weight average molecular weight was 6,800 in terms of standard polystyrene.

### Synthesis Example 3

In 155.36 g of propylene glycol monomethyl ether, 25.00 g of diglycidyl 2,6-naphthalenedicarboxylate obtained in Synthesis Example 1, 13.03 g of 5-hydroxyisophthalic acid, and 0.81 g of benzyltriethylammonium chloride were dissolved and the whole was reacted at 130° C. for 4 hours to give a polymer compound solution. Subjecting the obtained polymer compound to GPC analysis, it was revealed that the weight average molecular weight was 6,800 in terms of standard polystyrene.

### Synthesis Example 4

In 150.79 g of propylene glycol monomethyl ether, 25.00 g of diglycidyl 2,6-naphthalenedicarboxylate obtained in Synthesis Example 1, 11.88 g of isophthalic acid, and 0.81 g of benzyltriethylammonium chloride were dissolved and then the whole was reacted at 130° C. for 4 hours to give a polymer compound solution. Subjecting the obtained polymer compound to GPC analysis, it was revealed that the weight average molecular weight was 6,800 in terms of standard polystyrene.

### Example 1

To 2 g of the solution containing 0.4 g of the polymer compound obtained in Synthesis Example 3, 0.1 g of tetramethoxymethylglycoluril (manufactured by Nihon Cytec Industries Inc., trade name: Powderlink 1174) and 0.01 g of 5-sulfosalicylic acid were mixed, and the mixture was dissolved in 35.3 g of propylene glycol monomethyl ether and 15.9 g of cyclohexanone to make a solution. Then, the solution was filtered using a polyethylene microfilter having a pore size of 0.10 μm and further filtered using a polyethylene microfilter having a pore size of 0.05 μm to prepare a solution of a composition for forming a resist underlayer film.

### Example 2

To 2 g of the solution containing 0.4 g of the polymer compound obtained in Synthesis Example 4, 0.1 g of tetramethoxymethylglycoluril (manufactured by Nihon Cytec Industries Inc., trade name: Powderlink 1174) and 0.01 g of 5-sulfosalicylic acid were mixed, and the mixture was dissolved in 35.3 g of propylene glycol monomethyl ether and 15.9 g of cyclohexanone to make a solution. Then, the solution was filtered using a polyethylene microfilter having a pore size of 0.10 μm and further filtered using a polyethylene microfilter having a pore size of 0.05 μm to prepare a solution of a composition for forming a resist underlayer film.

### Comparative Example 1

To 2 g of the solution containing 0.4 g of the polymer compound obtained in Synthesis Example 2, 0.1 g of tetramethoxymethylglycoluril (manufactured by Nihon Cytec Industries Inc., trade name: Powderlink 1174) and 0.01 g of 5-sulfosalicylic acid were mixed, and the mixture was dissolved in 35.3 g of propylene glycol monomethyl ether and 15.9 g of cyclohexanone to make a solution. Then, the solution was filtered using a polyethylene microfilter having a pore size of 0.10 μm and further filtered using a polyethylene microfilter having a pore size of 0.05 μm to prepare a solution of a composition for forming a resist underlayer film.

[Dissolution Test in Resist Solvent]

Each solution of the composition for forming a resist underlayer film of the present invention prepared in Example 1 and Example 2 was applied onto a silicon wafer using a spinner (spin coat). The coated silicon wafer was heated on a hot plate at 205° C. for 1 minute to form a resist underlayer film (a film thickness of 0.10 μm). The resist underlayer film was immersed in ethyl lactate and propylene glycol monomethyl ether that are used as a solvent for a resist solution. It was ascertained that the resist underlayer film was insoluble in each solvent.

[Formation and Evaluation of Resist Pattern]

On a silicon wafer, each of the solutions of the compositions for forming a resist underlayer film of the present invention prepared in Example 1 and Example 2 and of the solution of the composition for forming a resist underlayer film prepared in Comparative Example 1 was spin-coated and heated at 205° C. for 1 minute to form a resist underlayer film. On the resist underlayer film, a negative-type resist solution for an electron beam (EB) (manufactured by Mitsubishi Gas Chemical Company, Inc.) was spin-coated and heated at 110° C. for 90 seconds. Then, EB was applied using an EB lithography system (manufactured by Elionix, ELS-7500) in a predetermined condition. After the exposure, the silicon wafer was heated (PEB) at 110° C. for 90 seconds, then cooled on a cooling plate to room temperature, and subjected to development and rinse treatment to form a resist pattern on the silicon wafer. Evaluation was conducted to determine whether 50 nm and 40 nm line-and-space patterns were formed or not (a composition that formed a good pattern is represented as “good”, and a composition that could not form a pattern is represented as “unacceptable”) and whether pattern line edge roughness (LER) was small or large by observation of the pattern from above.

Furthermore, as Comparative Example 2, a similar resist pattern was formed using no resist underlayer film and subjected to the evaluation.

TABLE 1

| | 50 nm | 40 nm | 50 nm | 40 nm |
|---|---|---|---|---|
| | pattern | pattern | pattern | pattern |
| | formation | formation | LER (nm) | LER (nm) |
| Example 1 | Good | Good | 2.4 | 2.4 |
| Example 2 | Good | Good | 2.4 | 2.4 |
| Comparative | Good | Unacceptable | 3.0 | — |
| Example 1 | | | | |
| Comparative | Unacceptable | Unacceptable | — | — |
| Example 2 | | | | |

(EUV Exposure Test)

On a silicon wafer, the solution of the composition for forming a resist underlayer film of the present invention prepared in Examples 1 was spin-coated and heated at 205° C. for 1 minute to form a resist underlayer film. On the resist underlayer film, a resist solution for EUV (methacrylate resin resist) was spin-coated followed by heating. The silicon wafer was exposed using an EUV exposure system (EUV-ADT manufactured by ASML) in a condition of NA=0.25 and σ=0.5. After the exposure, PEB (post exposure bake) was carried out, then the silicon wafer was cooled on a cooling plate to room temperature, and subjected to development and rinse treatment to form a resist pattern on the silicon wafer. Evaluation was conducted to determine whether a 30 nm line-and-space pattern was formed or not and whether pattern line edge roughness (LER) was small or large by observation of the pattern from above. A composition that could sufficiently form a 30 nm line-and-space pattern is represented as “good”, while a composition that was just enough to form the pattern is represented as “acceptable”. Furthermore, a fluctuation width of the formed 30 nm pattern is indicated in units of nm.

As Comparative Example 3, a silicon substrate was subjected to HMDS (hexamethyldisilazane) treatment using no resist underlayer film, and on the substrate, a resist solution for EUV (methacrylate resin resist) was spin-coated followed by heating. The silicon substrate was exposed using an EUV exposure system (EUV-ADT manufactured by ASML) in a condition of NA=0.25 and σ=0.5. After the exposure, PEB (post exposure bake) was carried out, then the silicon wafer was cooled on a cooling plate to room temperature, and subjected to development and rinse treatment to form a resist pattern on the silicon substrate. The substrate was also evaluated in a similar manner.

TABLE 2

| | 30 nm pattern | LER (nm) in |
|---|---|---|
| | formation | 30 nm pattern |
| Example 1 | Good | 3.7 |
| Comparative Example 3 | Acceptable | 4.5 |

### INDUSTRIAL APPLICABILITY

The present invention relates to a composition for forming a resist underlayer film for electron beam or EUV lithography that is used in a device manufacture process using electron beam or EUV lithography, reduces the adverse effects caused by an underlying substrate, an electron beam, or EUV, and is effective for the formation of a good resist pattern and a resist pattern formation method using the composition for forming a resist underlayer film.

1. A composition for forming a resist underlayer film for electron beam or EUV lithography, the composition comprising: a polymer having a repeating unit structure of Formula (1): 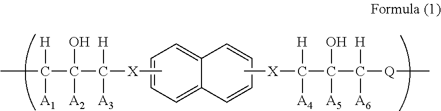
[where X is an ester linkage or an ether linkage; each of A₁, A₂, A₃, A₄, A₅, and A₆ is a hydrogen atom, a methyl group, or an ethyl group, and Q is a group of Formula (2) or Formula (3): 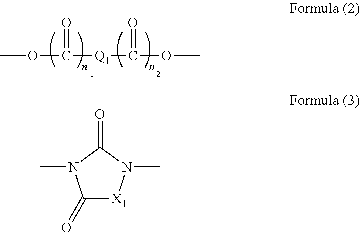
{where Q₁ is a C₁₋₁₀ alkylene group, a phenylene group, a naphthylene group, or an anthrylene group, and each of the phenylene group, the naphthylene group, and the anthrylene group is optionally substituted with a group selected from a group consisting of a C₁₋₆ alkyl group, a halogen atom, a C₁₋₆ alkoxy group, a nitro group, a cyano group, a hydroxy group, and a C₁₋₆ alkylthio group; each of n₁ and n₂ is a number of 0 or 1; and X₁ is a group of Formula (4), Formula (5), or Formula (6): 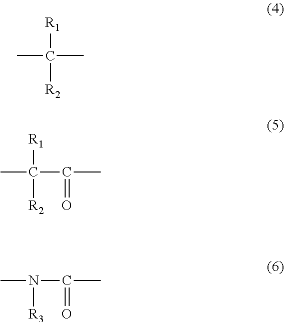
(where each of R₁ and R₂ is a hydrogen atom, a C₁₋₆ alkyl group, a C₂₋₆ alkenyl group, a benzyl group, or a phenyl group, the benzyl group and the phenyl group are optionally substituted with a group selected from a group consisting of a C₁₋₆ alkyl group, a halogen atom, a C₁₋₆ alkoxy group, a nitro group, a cyano group, a hydroxy group, and a C₁₋₆ alkylthio group, and R₁ and R₂ are optionally bonded to each other to form a C₃₋₆ ring; and R₃ is a C₁₋₆ alkyl group, a C₂₋₆ alkenyl group, a benzyl group, or a phenyl group, and the benzyl group and the phenyl group are optionally substituted with a group selected from a group consisting of a C₁₋₆ alkyl group, a halogen atom, a C₁₋₆ alkoxy group, a nitro group, a cyano group, a hydroxy group, and a C₁₋₆ alkylthio group)}]; and a solvent,

2. A composition for forming a resist underlayer film for electron beam or EUV lithography, the composition comprising
a polymer produced by polyaddition reaction of a compound of Formula (7): 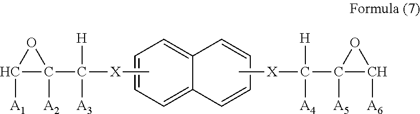
with a compound of Formula (8) or Formula (9): 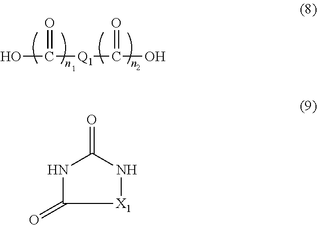
and a solvent
[where X is an ester linkage or an ether linkage; each of A₁, A₂, A₃, A₄, A₅, and A₆ is a hydrogen atom, a methyl group, or an ethyl group; Q₁ is a C₁₋₁₀ alkylene group, a phenylene group, a naphthylene group, or an anthrylene group, and each of the phenylene group, the naphthylene group, and the anthrylene group is optionally substituted with a group selected from a group consisting of a C₁₋₆ alkyl group, a halogen atom, a C₁₋₆ alkoxy group, a nitro group, a cyano group, a hydroxy group, and a C₁₋₆ alkylthio group; each of n₁ and n₂ is a number of 0 or 1; and X₁ is a group of Formula (4), Formula (5), or Formula (6): 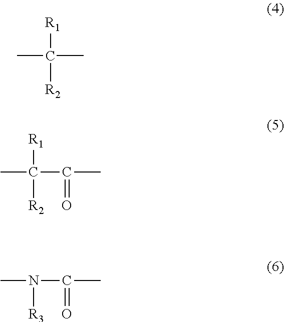
(where each of R₁ and R₂ is a hydrogen atom, a C₁₋₆ alkyl group, a C₂₋₆ alkenyl group, a benzyl group, or a phenyl group, the benzyl group and the phenyl group are optionally substituted with a group selected from a group consisting of a C₁₋₆ alkyl group, a halogen atom, a C₁₋₆ alkoxy group, a nitro group, a cyano group, a hydroxy group, and a C₁₋₆ alkylthio group, and R₁ and R₂ are optionally bonded to each other to form a C₃₋₆ ring; and R₃ is a C₁₋₆ alkyl group, a C₂₋₆ alkenyl group, a benzyl group, or a phenyl group, and the benzyl group and the phenyl group are optionally substituted with a group selected from a group consisting of a C₁₋₆ alkyl group, a halogen atom, a C₁₋₆ alkoxy group, a nitro group, a cyano group, a hydroxy group, and a C₁₋₆ alkylthio group)].

3. The composition for forming a resist underlayer film for electron beam or EUV lithography according to claim 2, wherein
the compound of Formula (7) is a compound of Formula (10) or Formula (11):

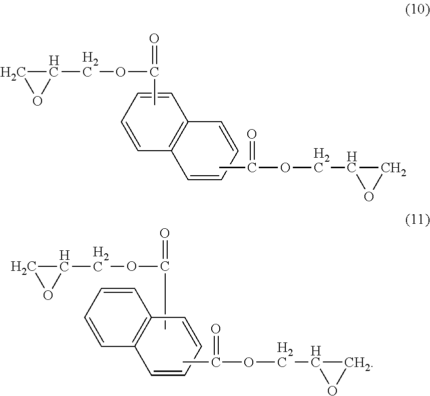

4. A composition for forming a resist underlayer film for electron beam or EUV lithography, the composition comprising
a polymer produced by polyaddition reaction of a compound of Formula (12): 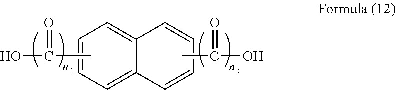
with a compound of Formula (13) or Formula (14): 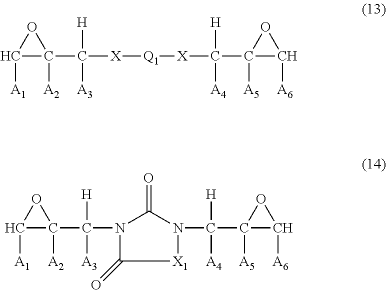
and a solvent
[where X is an ester linkage or an ether linkage; each of A₁, A₂, A₃, A₄, A₅, and A₆ is a hydrogen atom, a methyl group, or an ethyl group; Q₁ is a C₁₋₁₀ alkylene group, a phenylene group, a naphthylene group, or an anthrylene group, and each of the phenylene group, the naphthylene group, and the anthrylene group is optionally substituted with a group selected from a group consisting of a C₁₋₆ alkyl group, a halogen atom, a C₁₋₆ alkoxy group, a nitro group, a cyano group, a hydroxy group, and a C₁₋₆ alkylthio group; each of n₁ and n₂ is a number of 0 or 1; and X₁ is a group of Formula (4), Formula (5), or Formula (6): 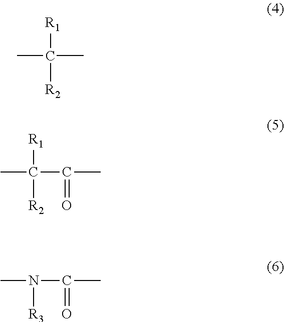
(where each of R₁ and R₂ is a hydrogen atom, a C₁₋₆ alkyl group, a C₂₋₆ alkenyl group, a benzyl group, or a phenyl group, the benzyl group and the phenyl group are optionally substituted with a group selected from a group consisting of a C₁₋₆ alkyl group, a halogen atom, a C₁₋₆ alkoxy group, a nitro group, a cyano group, a hydroxy group, and a C₁₋₆ alkylthio group, and R₁ and R₂ are optionally bonded to each other to form a C₃₋₆ ring; and R₃ is a C₁₋₆ alkyl group, a C₂₋₆ alkenyl group, a benzyl group, or a phenyl group, and the benzyl group and the phenyl group are optionally substituted with a group selected from a group consisting of a C₁₋₆ alkyl group, a halogen atom, a C₁₋₆ alkoxy group, a nitro group, a cyano group, a hydroxy group, and a C₁₋₆ alkylthio group)].

5. The composition for forming a resist underlayer film for electron beam or EUV lithography according to claim 4, wherein
the compound of Formula (12) is a compound of Formula (15) or Formula (16).

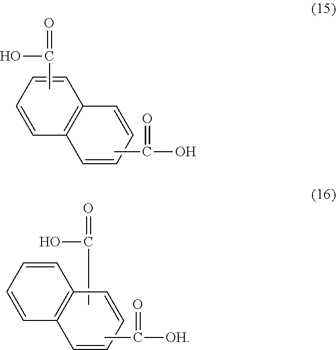

6. The composition for forming a resist underlayer film for electron beam or EUV lithography according to claim 1, the composition further comprising
a crosslinkable compound.

7. The composition for forming a resist underlayer film for electron beam or EUV lithography according to claim 6, wherein
the crosslinkable compound is a nitrogen-containing compound having two to four nitrogen atoms substituted with a methylol group or an alkoxymethyl group.

8. The composition for forming a resist underlayer film for electron beam or EUV lithography according to claim 1, the composition further comprising
an acid compound.

9. The composition for forming a resist underlayer film for electron beam or EUV lithography according to claim 8, wherein
the acid compound is a sulfonic acid compound.

10. The composition for forming a resist underlayer film for electron beam or EUV lithography according to claim 9, wherein
the acid compound is a combination of an iodonium salt-type acid generator or a sulfonium salt-type acid generator with the sulfonic acid compound.

11. A method for forming a photoresist pattern used for producing a semiconductor device, the method comprising:
applying the composition for forming a resist underlayer film according to claim 1 on a semiconductor substrate followed by baking the obtained substance to form a resist underlayer film;
forming a photoresist layer on the resist underlayer film;
exposing the semiconductor substrate coated with the resist underlayer film and the photoresist layer; and
developing the photoresist layer after the exposure.

12. The method for forming a photoresist pattern according to claim 11, wherein
the exposing is carried out by an electron beam or EUV having a wavelength of 13.5 nm.
